(19) United States
(12) Patent Application Publication
(10) Pub. No.: US 2019/0013302 A1
(43) Pub. Date: Jan. 10, 2019

(54) PACKAGING METHOD AND PACKAGE STRUCTURE FOR FINGERPRINT RECOGNITION CHIP AND DRIVE CHIP

(71) Applicant: China Wafer Level CSP Co., Ltd., Suzhou (CN)

(72) Inventors: Zhiqi Wang, Suzhou (CN); Guoliang Xie, Suzhou (CN); Hanqing Hu, Suzhou (CN)

(73) Assignee: China Wafer Level CSP Co., Ltd., Suzhou (CN)

(21) Appl. No.: 16/028,545

(22) Filed: Jul. 6, 2018

(30) Foreign Application Priority Data
Jul. 7, 2017 (CN) 201710551619.5
Jul. 7, 2017 (CN) 201720822769.0

(51) Int. Cl. H01L 25/16; H01L 25/00; H01L 21/78; H01L 23/00; H01L 21/768; H01L 21/683; H01L 23/528; H01L 23/522; G06K 9/00

(52) U.S. Cl. CPC H01L 25/16; H01L 21/3065; H01L 21/78; H01L 24/03; H01L 21/76898; H01L 24/11; H01L 21/6835; H01L 24/83; H01L 24/13; H01L 24/05; H01L 23/528; H01L 23/5226; H01L 24/94; H01L 24/27; H01L 21/76897; G06K 9/00087; H01L 2224/13024; H01L 2224/0231; H01L 2221/68327; H01L 2224/0401; H01L 2224/83005; H01L 2224/03002; H01L 2224/11002; H01L 2224/02372; H01L 2924/1433; H01L 2224/8385; H01L 2224/2919; H01L 2224/27618; H01L 2224/05025; H01L 2224/03614; H01L 25/50

(57) ABSTRACT

A packaging method and a package structure for a fingerprint recognition chip and a drive chip are provided. The packaging method is a wafer-level packaging method. According to the method, a blind hole is formed on the back surface of a wafer and the drive chip is secured in the blind hole, then the wafer is cut to obtain a package structure for the fingerprint recognition chip and the drive chip. In this way, the drive chip is packaged in the back surface of the wafer-level fingerprint recognition chip, thereby reducing the complexity of the package process. In addition, the size of the package structure is close to the size of the single fingerprint recognition chip, thereby greatly reducing the size of the package structure and improving the integration of the package structure.

### CROSS REFERENCE OF RELATED APPLICATION

This application claims the priority to Chinese Patent Application No. 201710551619.5, titled “PACKAGING METHOD AND PACKAGE STRUCTURE FOR FINGERPRINT RECOGNITION CHIP AND DRIVE CHIP”, filed on Jul. 7, 2017 with the State Intellectual Property Office of the People's Republic of China, which is incorporated herein by reference in its entirety.

### FIELD

The present disclosure relates to the technical field of semiconductors, and in particular to a packaging method and a package structure for a fingerprint recognition chip and a drive chip.

### BACKGROUND

With the continuous development of science and technology, personal identity identification and personal information security are gradually concerned by people. Due to the uniqueness and invariance of human fingerprints, the fingerprint recognition technology has good security and high reliability, and is simple and convenient to use. Therefore, the fingerprint recognition technology is widely applied in various fields of personal information protection and verification.

A fingerprint recognition device senses a fingerprint in a capacitive sensing mode by using multiple capacitive sensing electrodes or in an inductive sensing mode by using multiple inductive sensing electrodes. Since the epidermis or subcutaneous layer of a user finger has raised ridges and recessed valleys, when the user finger touches the surface of the sensing electrodes, the distance from the ridge to the surface of the sensing electrodes is different from the distance from the valley to the surface of the sensing electrodes, resulting in different capacitance values or inductance values between different regions of the finger and the sensing electrodes. By applying a drive signal to the sensing electrodes by a drive circuit, these differences are converted into electrical signals and are outputted, and fingerprint information of the user is obtained based on these electrical signals.

The current fingerprint recognition device is implemented by forming the sensing electrodes on a fingerprint recognition chip, and forming the drive circuit on a drive chip, and then packaging the fingerprint recognition chip and the drive chip together. Due to the continuously increased requirements on the device size, it is desired to provide a packaging method and a package structure for the fingerprint recognition chip and the drive chip, with which a small package size and a high integration can be achieved.

### SUMMARY

In view of the above, a packaging method for a fingerprint recognition chip and a drive chip is provided according to a first aspect of the present disclosure, with which the size of a package structure is reduced and an integration of the package structure is improved.

In order to solve the above issue, a packaging method for a fingerprint recognition chip and a drive chip is provided according to a first aspect of the present disclosure. The packaging method includes:

preparing a wafer and a drive chip, where the wafer has a first surface and a second surface facing away from the first surface, the first surface of the wafer is provided with a fingerprint recognition chip, the drive chip has a first surface and a second surface facing away from the first surface, and the first surface of the drive chip is provided with a drive circuit and a second contact pad;

forming a blind hole from the second surface of the wafer;

securing the drive chip in the blind hole, with the first surface of the drive chip being flush with the second surface of the wafer; and

cutting the wafer.

In an embodiment, the fingerprint recognition chip includes a sensing region and a first contact pad around the sensing region, and the blind hole is formed in a region corresponding to the sensing region of the fingerprint recognition chip.

In an embodiment, after the securing the drive chip in the blind hole and before the cutting the wafer, the packaging method further includes:

forming a through hole from the second surface of the wafer to expose the first contact pad;

forming a redistribution layer in the through hole and on the second surface of the wafer, with the redistribution layer being electrically connected to the first contact pad; and

forming a solder bump electrically connected to the redistribution layer and a solder bump electrically connected to the second contact pad.

In an embodiment, the forming the redistribution layer in the through hole and on the second surface of the wafer, with the redistribution layer being electrically connected to the first contact pad includes:

forming an insulative layer, where the insulative layer covers a side wall of the through hole, the second surface of the wafer and the first surface of the drive chip, and a first opening is formed on the insulative layer to expose the second contact pad; and

forming the redistribution layer in the through hole, and forming an electrical wiring layer in the first opening, where the redistribution layer is electrically connected to the first contact pad, the electrical wiring layer is electrically connected to the second contact pad, and the redistribution layer covers an inner wall of the through hole and extends to the second surface of the wafer.

In an embodiment, the forming the redistribution layer in the through hole and on the second surface of the wafer, with the redistribution layer being electrically connected to the first contact pad includes:

forming an insulative layer, where the insulative layer covers a side wall of the through hole, the second surface of the wafer and the first surface of the drive chip;

filling the through hole to form a metal plug on the first contact pad, with the metal plug being electrically connected to the first contact pad; and

forming the redistribution layer on the metal plug, and forming an electrical wiring layer on the second contact pad, where the redistribution layer is electrically connected to the metal plug, the electrical wiring layer is electrically connected to the second contact pad.

In an embodiment, the through hole is a stepped hole, and the forming the through hole from the second surface of the wafer to expose the first contact pad includes:

forming a groove from the second surface of the wafer, with the groove being located above the first contact pad;

forming a via hole in the groove to expose the first contact pad, to form the stepped hole, where the via hole has a one-to-one correspondence with the first contact pad; and

the forming the redistribution layer in the through hole and on the second surface of the wafer, with the redistribution layer being electrically connected to the first contact pad includes:

forming an insulative layer, where the insulative layer covers a side wall of the stepped hole, the second surface of the wafer and the first surface of the drive chip, the insulative layer is provided with a first opening, and the second contact pad is exposed by the first opening; and

forming the redistribution layer in the stepped hole, and forming an electrical wiring layer on the first opening, where the redistribution layer is electrically connected to the first contact pad, the electrical wiring layer is electrically connected to the second contact pad, and the redistribution layer covers an inner wall of the stepped hole and extends to the second surface of the wafer.

In an embodiment, the forming the solder bump electrically connected to the redistribution layer and the solder bump electrically connected to the second contact pad includes:

forming a solder-resist layer covering the second surface of the wafer, where the solder-resist layer is provided with second openings, and the redistribution layer and the electrical wiring layer are exposed by the second openings; and forming the solder bumps in the second openings.

In an embodiment, the forming the redistribution layer in the through hole and on the second surface of the wafer, with the redistribution layer being electrically connected to the first contact pad includes: forming an interconnecting layer electrically connecting the first contact pad with the second contact pad.

In an embodiment, after the preparing the wafer and before the forming the blind hole from the second surface of the wafer, the packaging method further includes: preparing a support substrate; and forming a first adhesive layer on the first surface of the wafer, and attaching the support substrate with the wafer by using the first adhesive layer.

In an embodiment, after the attaching the support substrate with the wafer by using the first adhesive layer and before the forming the blind hole from the second surface of the wafer, the packaging method further includes: thinning the wafer from the second surface of the wafer.

In an embodiment, the securing the drive chip in the blind hole includes: forming a second adhesive layer on an inner surface of the blind hole; and securing the drive chip in the blind hole by using the second adhesive layer, with the second surface of the drive chip facing the second adhesive layer.

In an embodiment, the cutting the wafer includes: removing the support substrate and then cutting the wafer to obtain a package structure for the fingerprint recognition chip and the drive chip.

In an embodiment, the cutting the wafer includes: cutting the wafer and then removing the support substrate to obtain a packaging structure for the fingerprint recognition chip and the drive chip.

A package structure for a fingerprint recognition chip and a drive chip is provided. The package structure includes a fingerprint recognition chip, a drive chip, and a blind hole.

The fingerprint recognition chip has a first surface and a second surface facing away from the first surface.

The drive chip has a first surface and a second surface facing away from the first surface, where the first surface of the drive chip is provided with a drive circuit and a second contact pad.

The blind hole is arranged on the second surface of the fingerprint recognition chip, where the drive chip is secured in the blind hole, and the first surface of the drive chip is flush with the second surface of the fingerprint recognition chip.

In an embodiment, the fingerprint recognition chip includes a sensing region and a first contact pad around the sensing region, and the blind hole is arranged in a region corresponding to the sensing region of the fingerprint recognition chip.

In an embodiment, the package structure further includes a through hole, a redistribution layer, and solder bumps.

The through hole is formed from the second surface of the fingerprint recognition chip to expose the first contact pad.

The redistribution layer is formed in the through hole and on the second surface of the fingerprint recognition chip and electrically connected to the first contact pad.

A solder bump is arranged on the redistribution layer and electrically connected to the redistribution layer, and a solder bump is arranged on the second contact pad and electrically connected to the second contact pad.

In an embodiment, the redistribution layer is formed in the through hole and electrically connected to the first contact pad, and the package structure further includes an insulative layer, and an electrical wiring layer which is electrically connected to the second contact pad.

The insulative layer covers a side wall of the through hole, the second surface of the fingerprint recognition chip and the first surface of the drive chip, the insulative layer is provided with a first opening and the second contact pad is exposed by the first opening, and the redistribution layer covers an inner wall of the through hole and extends to the second surface of the fingerprint recognition chip.

The electrical wiring layer is arranged on the first opening.

In an embodiment, the package structure further includes an insulative layer, a metal plug electrically connected to the first contact pad and an electrical wiring layer electrically connected to the second contact pad.

The insulative layer covers a side wall of the through hole, the second surface of the fingerprint recognition chip and the first surface of the drive surface.

The metal plug is arranged on the first contact pad, and fills up the through hole.

The redistribution layer is arranged on the metal plug.

The electrical wiring layer is arranged on the second contact pad.

In an embodiment, the through hole is a stepped hole, the stepped hole includes a groove arranged above the first contact pad and a via hole formed in the groove to expose the first contact pad, the via hole has a one to one correspondence with the first contact pad, the redistribution layer is formed in the stepped hole and is electrically connected to the first contact pad, and the package structure further includes an insulative layer, and an electrical wiring layer which is electrically connected to the second contact pad.

The insulative layer covers a side wall of the stepped hole, the second surface of the fingerprint recognition chip and the first surface of the drive chip, the insulative layer is provided with a first opening and the second contact pad is exposed by the first opening, the redistribution layer is formed on an inner wall of the stepped hole and extends to the second surface of the fingerprint recognition chip.

The electrical wiring layer is arranged on the first opening.

In an embodiment, the package structure further includes an interconnecting layer electrically connecting the first contact pad with the second contact pad.

In an embodiment, the package structure further includes a second adhesive layer arranged between the drive chip and an inner wall of the blind hole, where the drive chip is secured in the blind hole by using the second adhesive layer.

A wafer-level packaging method is adopted in the packaging method and the package structure for a fingerprint recognition chip and a drive chip according to the embodiments of the present disclosure. In the method, a blind hole is formed from the back surface of a wafer which faces away from the front surface on which the fingerprint recognition chip is provided, and the drive chip is secured in the blind hole, so as to package the fingerprint recognition chip and the drive chip. In this way, the drive chip is packaged in the back surface of the wafer-level fingerprint recognition chip, thereby reducing the complexity of the package process. In addition, the size of the package structure is close to the size of the single fingerprint recognition chip, thereby greatly reducing the size of the package structure and improving the integration of the package structure.

### BRIEF DESCRIPTION OF THE DRAWINGS

FIGS. 1A to 10 shows schematic structural diagrams of intermediate structures formed with a packaging method for a fingerprint recognition chip and a drive chip according to an embodiment of the present disclosure, where FIG. 1A is a top view, and FIG. 1 and FIGS. 3 to 10 are cross-sectional diagrams of the structure shown in FIG. 1A in a direction of AA1;

FIGS. 11 to 14 shows cross-sectional views of intermediate structures formed with a packaging method for a fingerprint recognition chip and a drive chip according to another embodiment of the present disclosure;

FIGS. 15 to 19 shows cross-sectional views of intermediate structures formed with a packaging method for a fingerprint recognition chip and a drive chip according to another embodiment of the present disclosure;

FIG. 20 shows a top view of a package structure for a fingerprint recognition chip and a drive chip according to an embodiment of the present disclosure;

FIG. 21 shows a cross-sectional view of a package structure for a fingerprint recognition chip and a drive chip according to an embodiment of the present disclosure;

FIG. 22 shows a cross-sectional view of a package structure for a fingerprint recognition chip and a drive chip according to another embodiment of the present disclosure; and

FIG. 23 shows a cross-sectional view of a package structure for a fingerprint recognition chip and a drive chip according to another embodiment of the present disclosure.

### DETAILED DESCRIPTION OF EMBODIMENTS

Specific details are described in the following description, so that the present disclosure can be understood fully. However, the present disclosure may also be embodied in other ways, and similar extension can be made by those skilled in the art without departing from intension of the present disclosure. Therefore, the present disclosure is not limited to the specific embodiments described below.

In addition, the present disclosure is described in detail in conjunction with the drawings. In the detail description of the present disclosure, the cross-sectional diagrams showing device structures are not drawn to scale, and the schematic diagrams are only examples and should not be construed to limit the scope of protection of the present disclosure. Moreover, a three-dimensional space size including length, width and depth should be included during an actual fabrication. In addition, the below structure that a first feature is “over” a second feature may include an embodiment that the first feature and the second feature form a direct contact, or an embodiment that another feature is formed between the first feature and the second feature. In this case, the first and second features may not contact each other directly.

In order to reduce the package size and improve the package integration of a fingerprint recognition chip and a drive chip, a packaging method for the fingerprint recognition chip and the drive chip is provided according to the present disclosure. The method includes: preparing a wafer and a drive chip, where the wafer has a first surface and a second surface facing away from the first surface, and the first surface of the wafer is provided with a fingerprint recognition chip, the drive chip has a first surface and a second surface facing away from the first surface, and the first surface of the drive chip is provided with a drive circuit and a second contact pad; forming a blind hole from the second surface of the wafer; securing the drive chip in the blind hole, with the first surface of the drive chip being flush with the second surface of the wafer; and cutting the wafer.

In the method, the drive chip is packaged in the back surface of the wafer-level fingerprint recognition chip, thereby reducing the complexity of the package process. Meanwhile, the size of the packaged fingerprint recognition chip and the drive chip is close to the size of a single fingerprint recognition chip, thereby greatly reducing the size of the package structure and improving the integration of the package structure.

Hereinafter, embodiments of the present disclosure are described in detail in conjunction with the drawings. Therefore, the above objectives, features and advantages of the present disclosure can be more apparent and easy-understanding. A packaging method for a fingerprint recognition chip and a drive chip according to the present disclosure includes steps S01 to S09.

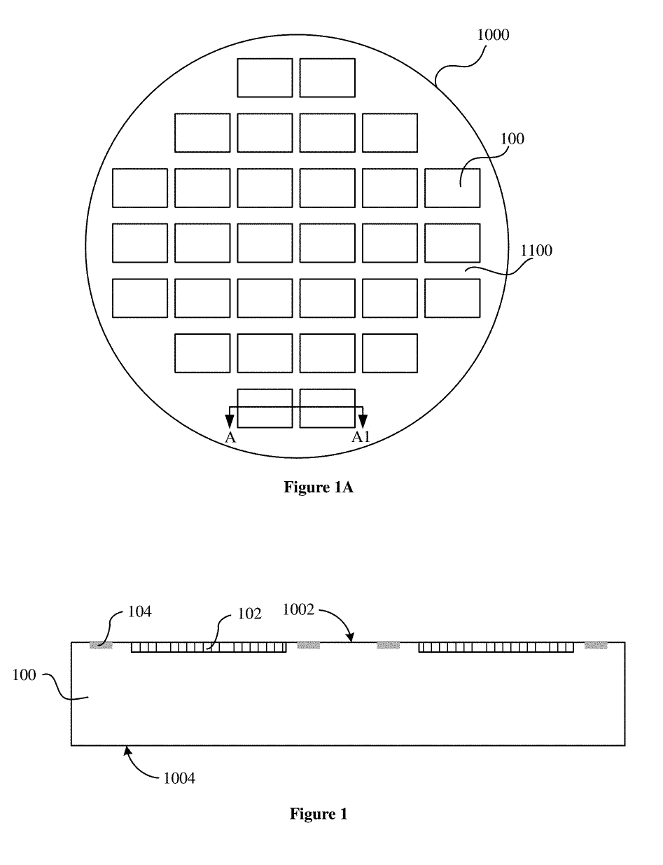

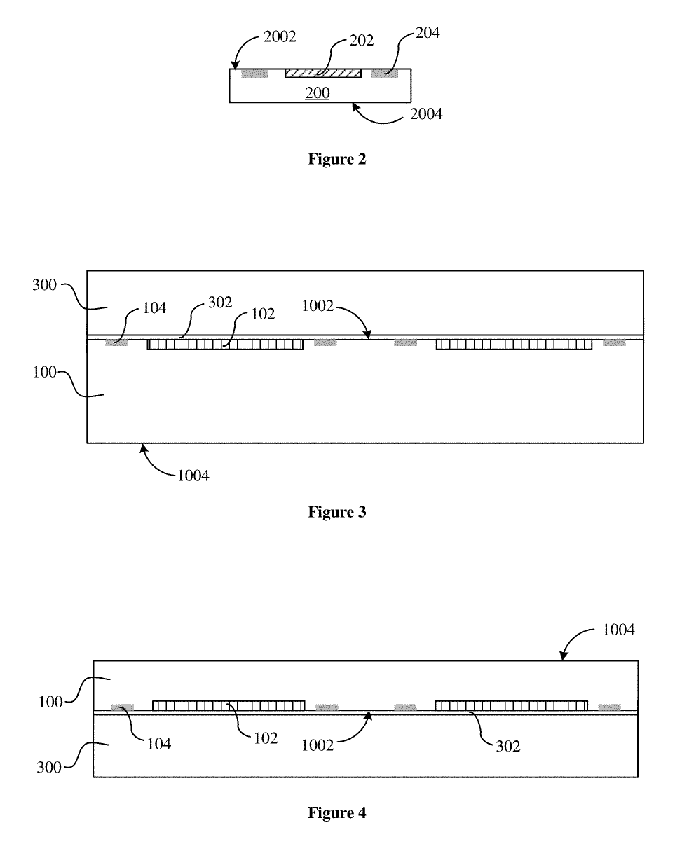

In step S01, as shown in FIGS. 1, 1A and 2, a wafer 1000 and a drive chip 200 are prepared. The wafer 1000 has a first surface 1002 and a second surface 1004 facing away from the first surface 1002. A fingerprint recognition chip 100 is formed on the first surface 1002 of the wafer 1000. The fingerprint recognition chip 100 includes a sensing region 102 and a first contact pad 104 around the sensing region 102. The drive chip 200 includes a first surface 2002 and a second surface 2004 facing away from the first surface 2002. The first face 2002 of the drive chip 200 is provided with a drive circuit 202 and a second contact pad 204.

The packaging method according to the embodiment of the present disclosure is a wafer-level packaging method and is performed on the wafer 1000 provided with the fingerprint recognition chip 100. As shown in FIG. 1A, the wafer 1000 is provided with the fingerprint recognition chips 100 arranged in an array. A cutting channel region 1100 is arranged between adjacent fingerprint recognition chips 100 for cutting the wafer 1000 in a subsequent process, to form a package structure of a single fingerprint recognition chip.

In the embodiment of the present disclosure, the fingerprint recognition chip 100 is configured to detect fingerprint information of a finger and generate an electrical signal. The drive chip 200 is configured to provide a drive signal to the fingerprint recognition chip 100. The drive chip 200 may be an Application Specific Integrated Circuit (ASIC) chip, which has a smaller area than the fingerprint recognition chip 100.

In the embodiment of the present disclosure, referring to FIG. 1, the fingerprint recognition chip 100 includes the sensing region 102 and the first contact pad 104 around the sensing region 102. The sensing region 102 and the first contact pad 104 are arranged on the first surface 1002. The sensing region 102 is configured to sense a fingerprint of a finger and generate an electrical signal. The sensing region 102 may include different types of sensing electrodes, for example, inductive sensing electrodes or capacitive sensing electrodes. The first contact pad 104 serves as an electric connection point for transmitting an electrical signal with an external chip or circuit. The fingerprint recognition chip 100 is further provided with an association circuit (not shown in the drawings). The association circuit is configured to electrically connect the sensing region 102 with the first contact pad 104, and the electrical signal generated by the sensing region 102 can be transmitted to the first contact pad 104 via the associated circuit.

Referring to FIG. 2, the drive chip 200 is a separate chip cut from the wafer. The drive chip 200 includes a drive circuit 202 and a second contact pad 204. The drive circuit 202 and the second contact pad 204 are located on the first surface 2002 of the drive chip 200. The drive circuit 202 is configured to provide a drive signal to the fingerprint recognition chip 100. The second contact pad 204 serves as an electrical connection point for transmitting an electrical signal with an external chip or a circuit. Further, the drive chip 200 is provided with an association circuit (not shown in the drawings) which electrically connects the drive circuit with the second contact pad.

In some embodiments, the sensing region 102 includes capacitive sensing electrodes. During fingerprint recognition, capacitances generated between the sensing region and different regions of a finger are different due to different distances from ridges and valleys of the finger to the surfaces of the sensing electrodes. The capacitances are detected by the sensing region 102, and are converted into electrical signals when the drive chip 200 applies drive signals to the sensing electrodes. An external circuit may acquire fingerprint information based on the electrical signals, and perform identity identification.

The above wafer 1000 provided with the fingerprint recognition chip 100 and the drive chip 200 may be formed by appropriate processes, which are not limited herein.

In step S02, a support substrate 300 is prepared. The support substrate 300 is arranged on the first surface 1002 of the wafer 1000, as shown in FIG. 3.

In a preferred embodiment of the present disclosure. The support substrate 300 is arranged on the first surface 1002 of the wafer 1000 for supporting and protecting the wafer 1000 in a subsequent process. The support substrate 300 is a temporary substrate and is removed when separate packages are formed.

The support substrate 300 may be made of any appropriate material, may be attached to the fingerprint recognition chip 100 by an adhesive for supporting and protecting the fingerprint recognition chip 100. In some embodiments, the support substrate 300 may be, for example, a Printed Circuit Board (PCB) substrate, a glass substrate, a metal substrate, a semiconductor substrate, a flexible polymer substrate, and the like.

In the embodiment, in order to facilitate subsequent removing of the support substrate, the support substrate 300 may be attached to the first surface 1002 of the wafer 1000 provided with the fingerprint recognition chip 100 by using a first adhesive layer 302. The first adhesive layer 302 may be made of silica gel, epoxy, benzocyclobutene, polyimide adhesive, polybenzoxazole adhesive, or other polymer adhesive materials.

The support substrate 300 may be attached to the first surface 1002 of the wafer 1000 provided with the fingerprint recognition chip 100 by using the first adhesive layer 302 with the following process. First, the first adhesive layer 302 is formed on the first surface 1002 of the wafer 1000 by a lamination process, a screen printing process or a roll coating process. Then, the support substrate 300 is attached with the first adhesive layer 302, such that the support substrate 300 is attached with the wafer 1000 by using the first adhesive layer 302, as shown in FIG. 3.

Further, in step S03, the wafer 1000 is thinned from the second surface 1004 of the wafer 1000, as shown in FIG. 4.

In the case that the wafer 1000 has a great thickness, the wafer 1000 may be first thinned from the second surface 1004, to facilitate subsequent etching to form the through hole. The wafer 1000 may be thinned by using mechanical-chemical polishing, chemical-mechanical polishing, or a combination thereof.

In step S04, a blind hole 110 is formed from the second surface 1004 of the wafer 1000. The blind hole 110 is formed in a region corresponding to the sensing region 102 of the fingerprint recognition chip 100, as shown in FIG. 5.

After the wafer 1000 is thinned, the blind hole 110 is formed from the second surface 1004 of the wafer 1000. The position and the depth of the blind hole 110 may be set as needed, and the size of the blind hole is set such that the blind hole can at least accommodate the drive chip.

In a preferred embodiment, as shown in FIG. 5, a region in which the blind hole 110 is formed corresponds to the sensing region 102 of the fingerprint recognition chip 100. The blind hole is formed in a region under the sensing region 102. It should be understood that, the blind hole 110 does not reach the sensing region 102. The size of the blind hole is determined depending on the size of the drive chip 200, and may be slightly greater than the size of the drive chip 200, for accommodating and securing the drive chip 200. Preferably, the depth of the blind hole 110 is determined depending on the thickness of the drive chip 200 and may be slightly greater than the thickness of the drive chip 200. After the drive chip 200 is secured, the first surface 2002 of the drive chip 200 is flush with the second surface 1004 of the wafer 1000.

The blind hole 110 is formed by an appropriate etching method selected based on the material of the wafer 1000. In an embodiment, the wafer 1000 has a silicon substrate. In this case, etching may be performed from the second surface 1004 of the wafer 1000 by using a silicon etching technology such as reactive ion etching and inductively coupled plasma etching, to form the blind hole 110, as shown in FIG. 5.

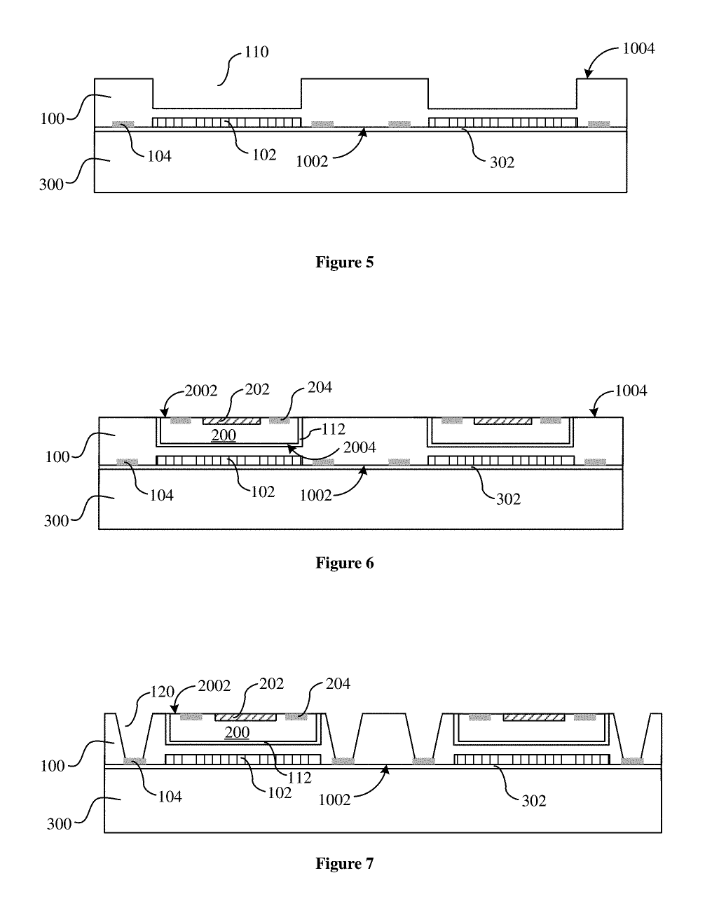

In step S05, the drive chip 200 is secured in the blind hole 110, and the first surface 2002 of the drive chip 200 is flush with the second surface 1004 of the wafer 1000, as shown in FIG. 6.

The drive chip 200 may be secured in the blind hole 110 with an appropriate method. In a preferred embodiment, the drive chip 200 is secured by using a second adhesive layer 112. The second adhesive layer 112 may be made of silica gel, epoxy, benzocyclobutene, polyimide, polybenzoxazole, or other polymer adhesive materials. Such method is simple and easy to perform. With this method, a certain degree of cushioning may be provided between the drive chip 200 and the fingerprint recognition chip 100.

The drive chip 200 may be secured in the blind hole 110 with the second adhesive layer 112 with the following process. First, a second adhesive material layer is formed on the second surface 1004 of the wafer with a lamination process, a screen printing process or a roll coating process. Then, the adhesive material layer is patterned by an exposing and developing process, to form the second adhesive layer 112 on only an inner wall of the blind hole 110.

Then, the drive chip 200 is attached with the second adhesive layer 112 with the second surface 2004 of the drive chip 200 facing the second adhesive layer 112, such that the drive chip 200 is secured in the blind hole 110 by using the second adhesive layer 112, and the first surface of the drive chip is flush with the second surface of the wafer.

The first surface 2002 of the drive chip 200 is flush with the second surface 1004 of the wafer 1000 after the drive chip 200 is secured in the blind hole 110, by appropriately setting the depth of the blind hole 110 and the thickness of the second adhesive layer 112 based on the thickness of the drive chip 200. Here, the first surface 2002 of the drive chip 200 being flush with the second surface 1004 of the wafer 1000 indicates that the first surface 2002 of the drive chip 200 and the second surface 1004 of the wafer 1000 are substantially in a same plane.

In the embodiment, during forming the blind hole 110, the depth of the blind hole 110 may be a sum of the thickness of the drive chip 200 and the thickness of the second adhesive layer 112, the length of the blind hole 110 may be a sum of the length of the drive chip 200 and the thickness of the second adhesive layer, and the width of the blind hole 110 may be a sum of the width of the drive chip 200 and the thickness of the second adhesive layer.

After the drive chip 200 is secured in the second surface 1004 of the wafer 1000, an outer lead of a contact pad is drawn and a bump of a contact pad is welded on the second surface 1004 of the wafer. The first contact pad and a second contact pad are formed on the second surface 1004 of the wafer 1000 and are drawn from the second surface of the wafer 1000, thereby further improving the integration of the package.

In a preferred embodiment, the outer leads of first contact pad 104 and the second contact pad 204 are drawn and the bumps of the first contact pad 104 and the second contact pad 204 are welded in steps S06 to S08.

In step S06, a through hole 120 is formed from the second surface 1004 of the wafer 1000 to expose the first contact pad 104, as shown in FIG. 7.

In the step, the through hole 120 is formed from the second surface 1004 of the wafer 1000, and an outer lead of the first contact pad 104 in the wafer 1000 is implemented by using the through hole 120.

As shown in FIG. 7, the through hole 120 is a Though Silicon Vias (TSV) hole. In this case, the through hole 120 is formed from the second surface 1004 of the wafer 1000 to expose the first contact pad 104 in the following way. The wafer 1000 is etched with an etching technology such as reactive ion etching and inductively coupled plasma etching until the first contact pad 104 is exposed. The first contact pad 104 may be further etched, that is, a portion of the thickness of the contact pad 104 is removed by etching. Hence, the through hole 120 via which the first contact pad 104 is exposed is formed.

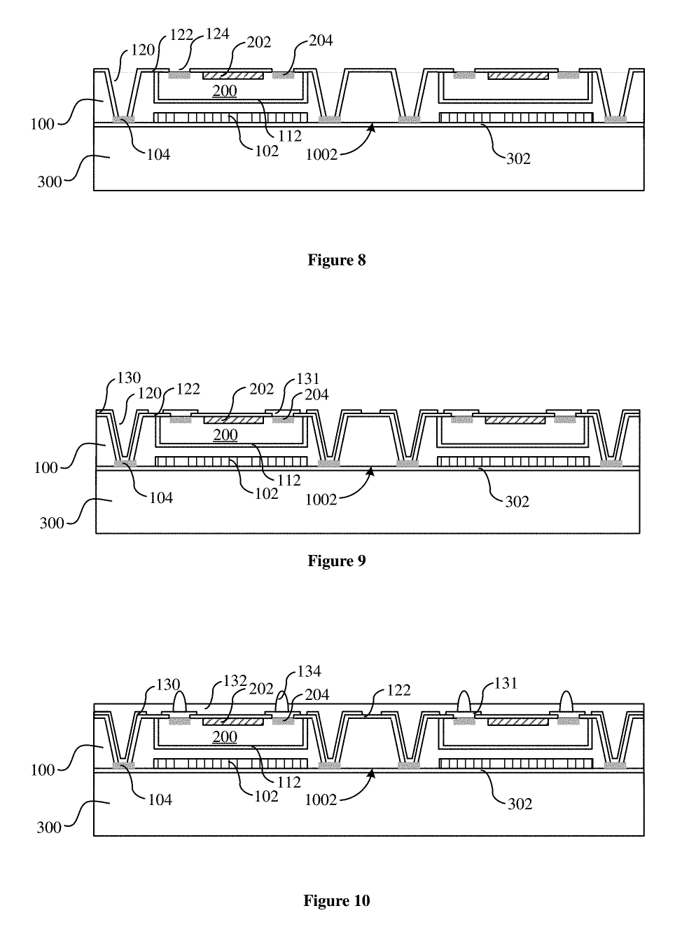

In step S07, a redistribution layer 130 is formed in the through hole 120 and on the second surface 1004 of the wafer 1000. The redistribution layer 130 is electrically connected to the first contact pad 104, as shown in FIGS. 8 to 9.

In step S08, solder bumps 134 are respectively formed on the redistribution layer 130 of the first contact pad 104 and on the second contact pad 204, as shown in FIG. 10.

In some preferred embodiments, as shown in FIGS. 8 to 10, the redistribution layer 130 is formed on an inner wall of the through hole 120 and on the second surface 1004 of the wafer 1000 and is electrically connected to the first contact pad 104, and the solder bump 134 are further formed, by steps S1081 to S1083.

In step S1081, an insulative layer 122 is formed. As shown in FIG. 8, the insulative layer 122 covers a side wall of the through hole 120, the second surface 1004 of the wafer 1000 and the first surface 2002 of the drive chip 200. The insulative layer 122 is provided with a first opening 124, and the second contact pad 204 is exposed by the first opening 124.

The insulative layer 122 is configured to electrically insulate the redistribution layer 130 from other portions of the fingerprint recognition chip. The insulative layer 122 may be made of dielectric material including oxide or nitride, such as silicon oxide, silicon nitride or silicon oxynitride or a stack thereof.

The insulating material may be deposited by using a chemical vapor deposition method, and then a mask is formed, and etching is performed under the masking of the mask to remove the insulating material on the first contact pad 104 and the second contact pad 204. In this way, the insulating layer 122 is formed only on the surface of the region other than the first contact pad 104 and the second contact pad 204, as shown in FIG. 8.

In step S1082, the redistribution layer 130 is formed in the through hole 120. The redistribution layer 130 is electrically connected to the first contact pad 104. An electrical wiring layer 131 is formed on the first opening 124. The electrical wiring layer 131 is electrically connected to the second contact pad 204, as shown in FIG. 9.

As shown in FIG. 9 and FIG. 10, the redistribution layer 130 is formed on the inner wall of the through hole 120, and a bottom portion of the redistribution layer 130 is in contact with a surface of the first contact pad 104, to form an electrical connection. Meanwhile, the redistribution layer 130 extends to a region corresponding to the sensing region of the fingerprint recognition chip, for formation of the solder bump 134.

In the preferred embodiment, the redistribution layer 130 and the electrical wiring layer 131 may be formed simultaneously, and may be made of a conductive material such as Al, Au, or Cu. The redistribution layer 130 and the electrical wiring layer 131 may be metal material films.

The redistribution layer 130 and the electrical wiring layer 131 may be formed simultaneously by using a redistribution layer (RDL) technology or other appropriate deposit processes. In an example, electroplating of Cu is performed by using the RDL technology, and Ti is sputtered for a prime coating, to form the redistribution layer 130 of the first contact pad 104 and the electrical wiring layer 131 of the second contact pad 204. With the RDL technology, welding regions are redistributed, thereby better meeting a requirement on a minimum space between solder bumps in the welding region. In these embodiments, the redistribution layer of the first contact pad is formed while the electrical wiring layer of the second contact pad is formed, so as to achieve high process integration.

In step S1083, a solder bump 134 is formed on the redistribution layer 130 of the first contact pad 104, the solder bump 134 being electrically connected to the redistribution layer 130. A solder bump 134 is formed on the electrical wiring layer 131, the solder bump 134 being electrically connected to the electrical wiring layer 131, as shown in FIG. 10.

Specifically, a solder-resist layer 132 is first formed. The solder-resist layer 132 serves as an insulative and protective layer for other layers in a bump-bonding process. The solder-resist layer 132 may be formed by, for example, solder-resist photosensitive ink, organic polymer photoresist, and the like.

Next, second openings (not shown in the drawings) are formed on the redistribution layer 130 of the first contact pad 104 and the electrical wiring layer 131 of the second contact pad 204. The redistribution layer 130 and the electrical wiring layer 131 are exposed via the second openings, for forming solder bumps. In an embodiment, the solder-resist layer is formed by solder-resist photosensitive ink by a spin-coating process, and the opening is formed on the solder-resist layer by an exposing and developing process.

Then, the solder bumps 134 are formed, as shown in FIG. 9. In an embodiment, an Under Bump Metal (UBM) may be first formed. Then, a ball placement process is performed to place a solder ball on the UBM with a mask plate. Next, the solder bump 134 is formed in the opening with a reflow soldering process. The solder bump may be a connection structure such as a solder ball and a metal post and may be made of a metal material such as copper, aluminum, gold, tin or lead, or an alloy material thereof.

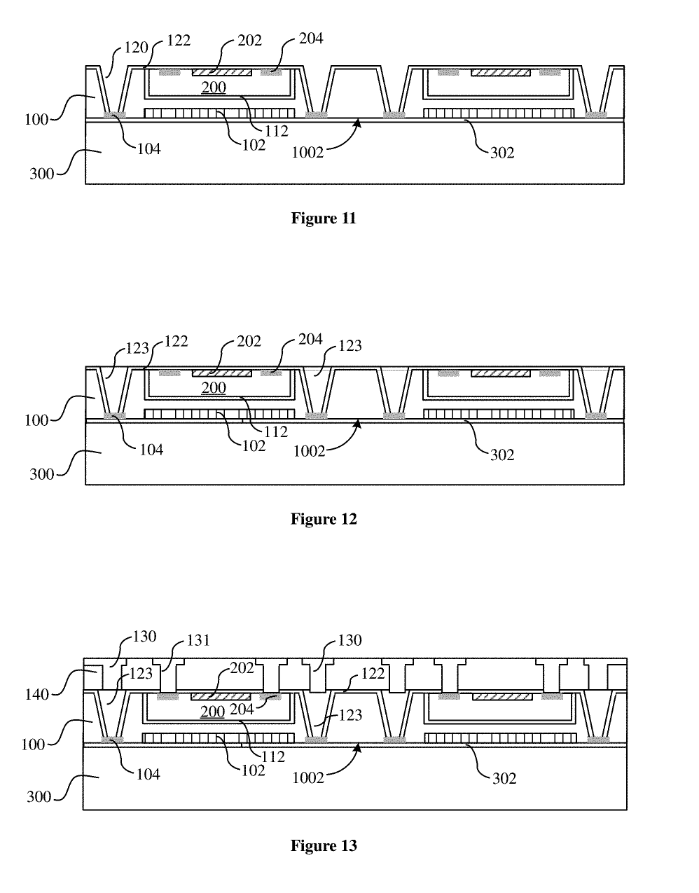

In other preferred embodiments, as shown in FIGS. 11 to 14, a metal plug may be formed by filling the through hole 120. The redistribution layer is formed on the metal plug and the solder bump 134 is further formed. A detailed process includes steps S2081 to S2084.

In step S2081, an insulative layer 122 is formed. As shown in FIG. 11, the insulative layer 122 covers a side wall of the through hole 120, the second surface 1004 of the wafer 1000 and the first surface 2002 of the drive chip 200.

Similar to step S1081, the insulative layer 130 is configured to electrically insulate the redistribution layer 130 from other portions of the fingerprint recognition chip. The insulative layer 122 may be made of dielectric material including oxide or nitride, such as silicon oxide, silicon nitride or silicon oxynitride or a stack thereof. The insulating material may be deposited by using a chemical vapor deposition method, and then a mask is formed, and etching is performed under the masking of the mask to remove the insulating material on the first contact pad 104. In this way, only the insulating layer on the first contact pad 104 is removed, as shown in FIG. 11.

In step S2082, the through hole is filled to form a metal plug 123 on the first contact pad 104. The metal plug 123 is electrically connected to the first contact pad 104, as shown in FIG. 12.

In these embodiments, the through hole is filled up with metal material such as W and Cu. The through hole may be filled by using a W-plug process or a Cu electroplating process, to form the metal plug 123 on the first contact pad 104.

In step S2083, a redistribution layer 130 is formed on the metal plug 123 and an electrical wiring layer 131 is formed on the second contact pad 204, as shown in FIG. 13.

The redistribution layer 130 and the electrical wiring layer 131 may be formed with one or more metal interconnecting layers by an interconnecting process as needed. The metal interconnecting layer may be made of a metal material such as Al, Au and Cu. In an example, a dielectric layer 140 may be first formed. Then, the redistribution layer 130 and the electrical wiring layer 131 are formed by Cu on the metal plug 123 and the second contact pad 204 with a damascene process, respectively, as shown in FIG. 13.

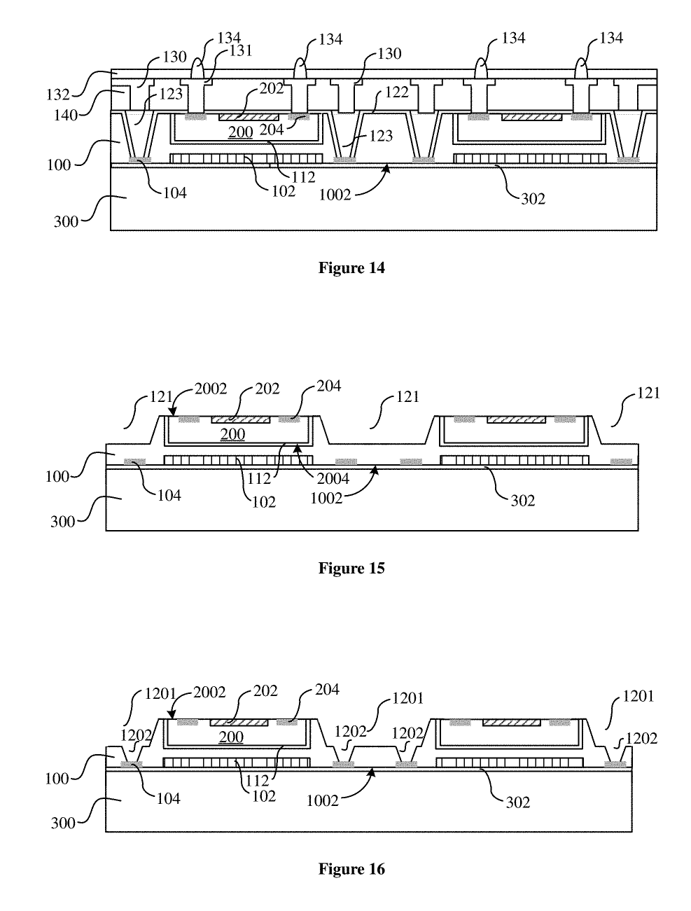

In step S2084, a solder bump 134 is formed on the redistribution layer 130 corresponding to the first contact pad 104, the solder bump 134 being electrically connected to the redistribution layer 130, and a solder bump 134 is formed on the electrical wiring layer 131, the solder bump 134 being electrically connected to the electrical wiring layer 131, as shown in FIG. 14.

Specifically, a solder-resist layer 132 is first formed. The solder-resist layer 132 serves as an insulative and protective layer for other layers in a bump-bonding process. The solder-resist layer 132 may be formed with, for example, solder-resist photosensitive ink, organic polymer photoresist, and the like.

Next, second openings (not shown in the drawings) are formed on the redistribution layer 130 corresponding to the first contact pad 104 and the electrical wiring layer 131 of the second contact pad 204. The redistribution layer 130 and the electrical wiring layer 131 are exposed via the second openings, for forming solder bumps. In an embodiment, the solder-resist layer is formed by solder-resist photosensitive ink. The solder-resist photosensitive ink is spin coated and the opening is formed by an exposing and developing process.

Then, the solder bump 134 is formed, as shown in FIG. 14. In an embodiment, a UBM may be first formed. Then, a ball placement process is performed to place a solder ball on the UBM with a mask plate. Next, the solder bump 134 is formed in the opening with a reflow soldering process. The solder bump may be a connection structure such as a solder ball and a metal post, and may be made of a metal material such as copper, aluminum, gold, tin or lead, or an alloy material thereof.

In some preferred embodiments, as shown in FIGS. 15 to 19, the through hole 120 is a stepped hole. The stepped hole is formed by using a method including a step S3601.

In step S3601, first, a groove 121 is formed from the second surface 1004 of the wafer 1000, the groove 1201 is located above the first contact pad 104.

The wafer 1000 may be etched by using an etching technology such as reactive ion etching or inductively coupled plasma etching, to form the groove 1201 above the first contact pad 104, as shown in FIG. 15.

Then, a via hole 1202 is formed in the groove 1201 to expose the first contact pad 104, to form a stepped hole. The via hole 1202 has a one-to-one correspondence with the first contact pad 104.

The wafer 1000 may be further etched in the groove by using the etching technology such as reactive ion etching or inductively coupled plasma etching, until the first contact pad 104 is exposed, thereby forming the via hole 1202, such that the stepped hole is formed, as shown in FIG. 16.

After the stepped hole (1201 and 1202) is formed, a redistribution layer 130 is formed in the stepped hole, the redistribution layer 130 is electrically connected to the first contact pad. The redistribution layer extends to the second surface 1004 of the wafer. Then, a solder bump 134 is formed on the redistribution layer 130.

The redistribution layer 130 is formed by steps S3081 to S3082.

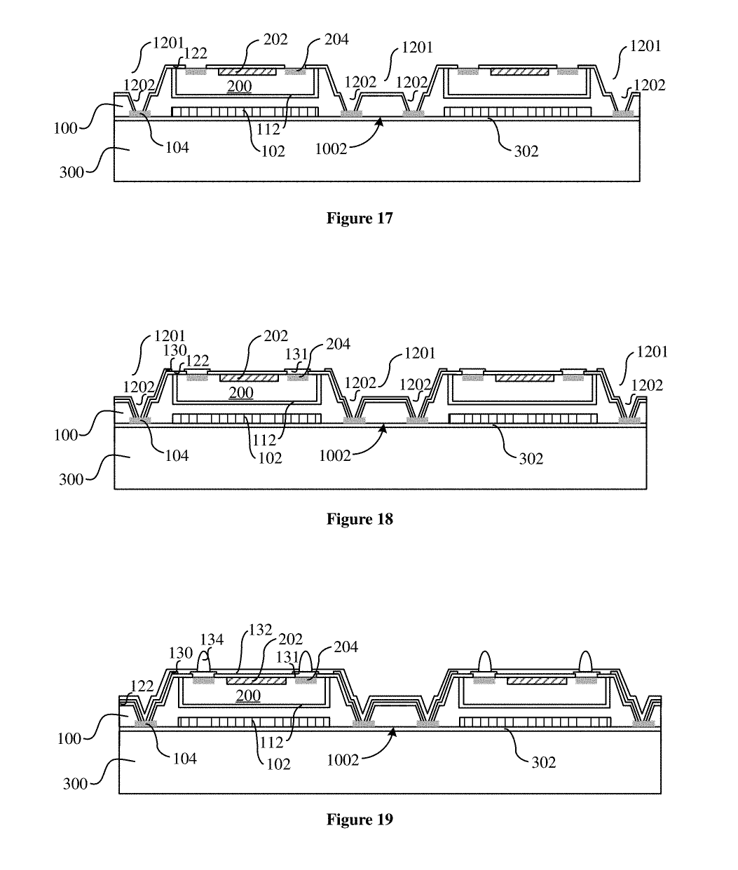

In step S3081, an insulative layer 122 is formed. As shown in FIG. 17, the insulative layer 122 covers side walls of the stepped holes 1201 and 1202, the second surface 1004 of the wafer 1000 and the first surface 2002 of the drive chip 200. The insulative layer 122 is provided with a first opening 124, and the second contact pad 204 is exposed via the first opening 124.

The insulative layer 122 is configured to electrically insulate the redistribution layer 130 from other portions of the fingerprint recognition chip. The insulative layer 122 may be made of a dielectric material including oxide or nitride, such as silicon oxide, silicon nitride or silicon oxynitride or a stack thereof.

The insulating material may be deposited by using a chemical vapor deposition method, and then a mask is formed, and etching is performed under the masking of the mask to remove the insulating material on the first contact pad 104 and the second contact pad 204. In this way, the insulating layer 122 is formed only on the surface of the region other than the first contact pad 104 and the second contact pad 204, as shown in FIG. 17.

In step S3082, the redistribution layer 130 is formed in the stepped hole. The redistribution layer 130 is electrically connected to the first contact pad 104. An electrical wiring layer 131 is formed on the first opening 124. The electrical wiring layer 131 is electrically connected to the second contact pad 204, as shown in FIG. 18.

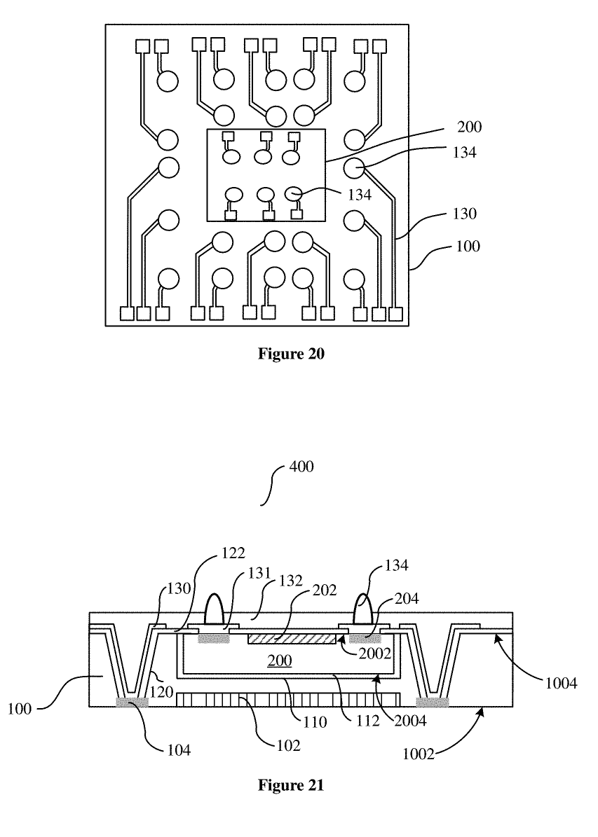

As shown in FIG. 19 and FIG. 20, the redistribution layer 130 is formed on the inner wall of the stepped hole and a bottom portion of the redistribution layer 130 is in contact with a surface of the first contact pad 104, to form an electrical connection. Meanwhile, the redistribution layer 130 extends to a region corresponding to the sensing region of the fingerprint recognition chip, for formation of the solder bump 134.

In the preferred embodiment, the redistribution layer 130 and the electrical wiring layer 131 may be formed simultaneously, and may be made of a conductive material such as Al, Au, or Cu. The redistribution layer 130 and the electrical wiring layer 131 may be metal material films.

The redistribution layer 130 and the electrical wiring layer 131 may be formed simultaneously by using the RDL technology or other appropriate deposit processes. As shown in FIG. 18, in an example, electroplating of Cu is performed by using the RDL technology, and Ti is sputtered for a prime coating, to form the redistribution layer 130 of the first contact pad 104 and the electrical wiring layer 131 of the second contact pad 204. With the RDL technology, welding regions are redistributed, thereby better meeting a requirement on a minimum space between solder bumps in the welding region. In these embodiments, the redistribution layer of the first contact pad is formed while the electrical wiring layer of the second contact pad is formed, so as to achieve high process integration.

In step S3083, a solder bump 134 is formed on the redistribution layer 130 of the first contact pad 104, the solder bump 134 being electrically connected to the redistribution layer 130, and a solder bump 134 is formed on the electrical wiring layer 131, the solder bump 134 being electrically connected to the electrical wiring layer 131, as shown in FIG. 19.

Specifically, a solder-resist layer 132 is first formed. The solder-resist layer 132 serves as an insulative and protective layer for other layers in a bump-bonding process. The solder-resist layer 132 may be formed by, for example, solder-resist photosensitive ink, organic polymer photoresist, and the like.

Next, second openings (not shown in the drawings) are formed on the redistribution layer 130 of the first contact pad 104 and the electrical wiring layer 131 of the second contact pad 204. The redistribution layer 130 and the electrical wiring layer 131 are exposed via the second openings, for forming solder bumps. In an embodiment, the solder-resist layer is formed by solder-resist photosensitive ink. The solder-resist photosensitive ink is spin coated and the opening is formed by an exposing and developing process.

Then, the solder bump 134 is formed, as shown in FIG. 19. In an embodiment, a UBM may be first formed. Then, a ball placement process is performed to place a solder ball on the UBM with a mask plate. Next, the solder bump 134 is formed in the opening with a reflow soldering process. The solder bump may be a connection structure such as a solder ball and a metal post, and may be made of a metal material such as copper, aluminum, gold, tin or lead, or an alloy material thereof.

In the above embodiments, when the redistribution layer 130 is formed, an interconnecting layer (not shown in the drawings) may be formed to electrically connect the first contact pad 104 with the second contact pad 204 as needed. Further, the interconnecting layer may be formed simultaneously with the redistribution layer 130. By forming the interconnecting layer between the redistribution layer 130 and the electrical wiring layer 131 which need to be interconnected, the first contact pad 104 which is electrically connected to the redistribution layer is electrically connected to the second contact pad 204 which is electrically connected to the electrical wiring layer.

In step S09, the wafer 1000 is cut to obtain a package structure for the fingerprint recognition chip 100 and the drive chip 200, as shown in FIGS. 20 to 23.

In the step, as shown in FIGS. 21 to 23, the support substrate 300 may be first removed, and then the wafer 1000 is cut, to obtain a package structure for the fingerprint recognition chip 100 and the drive chip 200. Alternatively, the wafer 1000 may be first cut, and then the support substrate 300 is removed, to obtain a package structure for the fingerprint recognition chip 100 and the drive chip 200.

The wafer 1000 is cut along the cutting channel region 1100 of the wafer 1000. In this way, the above package structure for the wafer is cut into separated chips, so as to obtain the package structure for the fingerprint recognition chip 100 and the drive chip 200.

Reference is made to FIG. 20, which is a top view of the second surface 1004 of the package structure for the fingerprint recognition chip 100 and the drive chip 200. As can be seen, the drive chip 200 is packaged into the second surface 1004 of the package structure, solder bumps 134 of the two chips are formed on the plane where the second surface 1004 of the fingerprint recognition chip 100 is located. In this case, electrical signals from the two chips can be collected, thereby effectively reducing the size and improving the integration of the package structure.

In the above, the packaging method for a fingerprint recognition chip and a drive chip according to the embodiments of the present disclosure is described. In addition, a package structure for a fingerprint recognition chip and a drive chip formed with the above method is further provided according to the present disclosure. As shown in FIGS. 20 to 23, the package structure for the fingerprint recognition chip and the drive chip includes a fingerprint recognition chip 100, a drive chip 200 and a blind hole 220.

The fingerprint recognition chip 100 has a first surface 1002 and a second surface 1004 facing away from the first surface 1002.

The drive chip 200 has a first surface 2002 and a second surface 2004 facing away from the first surface 2002, where the first surface 2002 of the drive chip 200 is provided with a drive circuit 202 and a second contact pad 204;

The blind hole 110 is arranged on the second surface 1004 of the fingerprint recognition chip 100, where the drive chip 200 is secured in the blind hole 110, and the first surface 2002 of the drive chip 200 is flush with the second surface 1004 of the fingerprint recognition chip 100.

In the embodiment of the present disclosure, the fingerprint recognition chip 100 includes the sensing region 102 and the first contact pad 104 around the sensing region 102. The sensing region 102 and the first contact pad 104 are arranged on the first surface 1002. The sensing region 102 is configured to detect a fingerprint signal. The first contact pad 104 is electrically connected to an external circuit. The sensing region 102 may include recognition components with different sensing modes, for example, inductive or capacitive sensing mode. In some embodiments, the sensing region 102 includes an inductive recognition component. During fingerprint recognition, the sensing region 102 detects a capacitance, converts the capacitances into an electrical signal. The external circuit may acquire fingerprint information based on the electrical signal, for identity identification.

The drive chip 200 includes a drive circuit 202 and a second contact pad 204. The drive circuit 202 and the second contact pad 204 are arranged on the first surface 2002 of the drive chip 200. The drive circuit 202 is configured to provide a drive signal to the fingerprint recognition chip 100, and the second contact pad 204 is electrically connected to an external circuit. The drive chip 200 may be an ASIC chip and has a smaller area than the fingerprint recognition chip 100.

In a preferred embodiment, a region in which the blind hole 110 is formed corresponds to the sensing region 102 of the fingerprint recognition chip 100. The blind hole is formed in a region under the sensing region 102. It should be understood that, the blind hole 110 does not reach the sensing region 102. The size of the blind hole 110 is determined depending on the size of the drive chip 200, and may be slightly greater than the size of the drive chip 200, for accommodating and securing the drive chip 200. Further, the depth of the blind hole 110 is determined depending on the thickness of the drive chip 200 and may be slightly greater than the thickness of the drive chip 200. After the drive chip 200 is secured, the first surface 2002 of the drive chip 200 is flush with the second surface 1004 of the fingerprint recognition chip 100. Here, the first surface 2002 of the drive chip 200 being flush with the second surface 1004 of the fingerprint recognition chip 100 indicates that the first surface 2002 of the drive chip 200 and the second surface 1004 of the fingerprint recognition chip 100 are substantially in a same plane.

In some embodiments, an adhesive layer 112 is arranged between the blind hole 110 and the drive chip 200, and the drive chip 200 is secured in the blind hole 110 by using the adhesive layer 112. The depth of the blind hole 110 may be a sum of the thickness of the drive chip 200 and the thickness of the adhesive layer 112, the length of the blind hole 110 may be a sum of the length of the drive chip 200 and the thickness of the adhesive layer 112, and the width of the blind hole 110 may be a sum of the width of the drive chip 200 and the thickness of the adhesive layer 112. The adhesive layer may be made of silica gel, epoxy, benzocyclobutene, polyimide, polybenzoxazole, or the like.

In the embodiment of the present disclosure, the first contact pad 104 may be electrically led to the second surface 1004 of the fingerprint recognition chip 100 via the through hole 120. Components for the electrical leading-out include the through hole 120, the redistribution layer 130 and solder bumps 134.

The through hole 120 is formed from the second surface 1004 of the fingerprint recognition chip 100 to expose the first contact pad 104.

The redistribution layer 130 is arranged in the through hole 120 and on the second surface 1004 of fingerprint recognition chip 100 and is electrically connected to the first contact pad 104.

A solder bump 134 is formed on the redistribution layer 130, the solder bump 134 is electrically connected to the redistribution layer 130. A solder bump 134 is formed on the second contact pad 204, the solder bump 134 is electrically connected to the second contact pad 204.

In some preferred embodiments, as shown in FIG. 21, the first contact pad 104 is electrically led out by forming the redistribution layer in the through hole 120. The redistribution layer 130 is formed in the through hole 120 and is electrically connected to the first contact pad 104. The structure further includes an insulative layer 122, and an electrical wiring layer 131 which is electrically connected to the second contact pad. The insulative layer 122 covers a side wall of the through hole, the second surface 1004 of the fingerprint recognition chip 100 and the first surface 2002 of the drive chip 100. The insulative layer 122 is provided with a first opening via which the second contact pad 204 is exposed. The redistribution layer 130 covers an inner wall of the through hole and extends to the second surface 1004 of the fingerprint recognition chip 100. The electrical wiring layer 131 is arranged on the first opening.

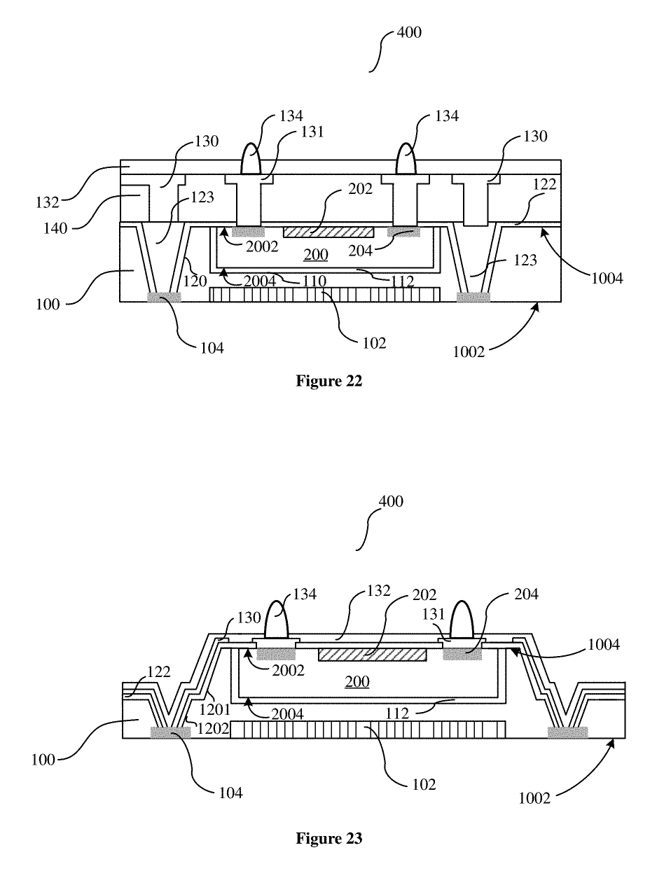

In some other preferred embodiments, the first contact pad 104 is electrically led out by forming a metal plug 123 in the through hole 120. As shown in FIG. 22, the structure further includes the insulative layer 122, the metal plug 123 electrically connected to the first contact pad 104 and an electrical wiring layer 131 electrically connected to the second contact pad 204. The insulative layer 122 covers the side wall of the through hole, the second surface 1004 of the fingerprint recognition chip 100 and the first surface 2002 of the drive chip 200. The metal plug 123 is arranged on the first contact pad 104 and fills up the through hole 120. The redistribution layer 130 is arranged on the metal plug 123, and the electrical wiring layer 131 is arranged on the second contact pad 204.

In some preferred embodiments, the through hole is a stepped hole (1201 and 1202), and the first contact pad 104 is electrically led out by forming the redistribution layer 130 in the stepped hole. As shown in FIG. 23, the stepped hole includes a groove 1201 above the first contact pad and a via hole 1202. The via hole 1202 is arranged in the groove 1201, and the first contact pad 104 is exposed via the via hole 1202. The via hole 1202 and the first contact pad 104 have a one-to-one correspondence. The redistribution layer 130 is formed in the stepped hole and is electrically connected to the first contact pad 104. The structure further includes the insulative layer 122 and the electrical wiring layer 131 of the second contact pad 204. The insulative layer 122 is arranged on a side wall of the stepped hole, the second surface 1004 of the fingerprint recognition chip 100 and the first surface 2002 of the drive chip 200. In addition, the insulative layer 122 is provided with a first opening via which the second contact pad 204 is exposed. The redistribution layer 130 is arranged on an inner wall of the stepped hole and extends to the second surface 1004 of the fingerprint recognition chip 100. The electrical wiring layer 131 is arranged on the first opening.

Further, the package structure further includes an interconnecting layer (not shown in the drawings) configured to electrically connect the first contact pad 104 with the second contact pad 204.

In the package structure for the fingerprint recognition chip and the drive chip according to the embodiments of the present disclosure, the drive chip is packaged in a back surface of the fingerprint recognition chip, thereby reducing the complexity of the package process. Meanwhile, the size of the structure obtained by the packaging is close to the size of a single fingerprint recognition chip, thereby greatly reducing the size of the package structure and improving the integration of the package structure.

The preferred embodiments of the present disclosure are disclosed above, which should not be interpreted as limiting the present disclosure. Numerous alternations and modifications can be made to the technical solutions of the present disclosure by those skilled in the art in light of the methods and technical content disclosed herein without deviation from the scope of the present disclosure. Therefore, any simple modifications, equivalents, and improvements made to the above embodiments according to the technical essential of the present disclosure without deviation from the content of the technical solutions of the present disclosure should fall within the scope of protection of the present disclosure.

1. A packaging method for a fingerprint recognition chip and a drive chip, comprising:
preparing a wafer and a drive chip, wherein the wafer has a first surface and a second surface facing away from the first surface, the first surface of the wafer is provided with a fingerprint recognition chip, the drive chip has a first surface and a second surface facing away from the first surface, and the first surface of the drive chip is provided with a drive circuit and a second contact pad;
forming a blind hole from the second surface of the wafer;
securing the drive chip in the blind hole, with the first surface of the drive chip being flush with the second surface of the wafer; and
cutting the wafer.

2. The packaging method according to claim 1, wherein the fingerprint recognition chip comprises a sensing region and a first contact pad around the sensing region, and the blind hole is formed in a region corresponding to the sensing region of the fingerprint recognition chip.

3. The packaging method according to claim 2, wherein after the securing the drive chip in the blind hole and before the cutting the wafer, the packaging method further comprises:
forming a through hole from the second surface of the wafer to expose the first contact pad;
forming a redistribution layer in the through hole and on the second surface of the wafer, with the redistribution layer being electrically connected to the first contact pad; and
forming a solder bump electrically connected to the redistribution layer and a solder bump electrically connected to the second contact pad.

4. The packaging method according to claim 3, wherein the forming the redistribution layer in the through hole and on the second surface of the wafer, with the redistribution layer being electrically connected to the first contact pad comprises:
forming an insulative layer, wherein the insulative layer covers a side wall of the through hole, the second surface of the wafer and the first surface of the drive chip, and a first opening is formed on the insulative layer to expose the second contact pad; and
forming the redistribution layer in the through hole, and forming an electrical wiring layer in the first opening, wherein the redistribution layer is electrically connected to the first contact pad, the electrical wiring layer is electrically connected to the second contact pad, and the redistribution layer covers an inner wall of the through hole and extends to the second surface of the wafer.

5. The packaging method according to claim 3, wherein the forming the redistribution layer in the through hole and on the second surface of the wafer, with the redistribution layer being electrically connected to the first contact pad comprises:
forming an insulative layer, wherein the insulative layer covers a side wall of the through hole, the second surface of the wafer and the first surface of the drive chip;
filling the through hole to form a metal plug on the first contact pad, with the metal plug being electrically connected to the first contact pad; and
forming the redistribution layer on the metal plug, and forming an electrical wiring layer on the second contact pad, wherein the redistribution layer is electrically connected to the metal plug, the electrical wiring layer is electrically connected to the second contact pad.

6. The packaging method according to claim 3, wherein the through hole is a stepped hole, and the forming the through hole from the second surface of the wafer to expose the first contact pad comprises:
forming a groove from the second surface of the wafer, with the groove being located above the first contact pad;
forming a via hole in the groove to expose the first contact pad, to form the stepped hole, wherein the via hole has a one-to-one correspondence with the first contact pad; and
the forming the redistribution layer in the through hole and on the second surface of the wafer, with the redistribution layer being electrically connected to the first contact pad comprises:
forming an insulative layer, wherein the insulative layer covers a side wall of the stepped hole, the second surface of the wafer and the first surface of the drive chip, the insulative layer is provided with a first opening, and the second contact pad is exposed by the first opening; and
forming the redistribution layer in the stepped hole, and forming an electrical wiring layer on the first opening, wherein the redistribution layer is electrically connected to the first contact pad, the electrical wiring layer is electrically connected to the second contact pad, and the redistribution layer covers an inner wall of the stepped hole and extends to the second surface of the wafer.

7. The packaging method according to claim 4, wherein the forming the solder bump electrically connected to the redistribution layer and the solder bump electrically connected to the second contact pad comprises:
forming a solder-resist layer covering the second surface of the wafer, wherein the solder-resist layer is provided with second openings, and the redistribution layer and the electrical wiring layer are exposed by the second openings; and
forming the solder bumps in the second openings.

8. The packaging method according to claim 4, wherein the forming the redistribution layer in the through hole and on the second surface of the wafer, with the redistribution layer being electrically connected to the first contact pad comprises:
forming an interconnecting layer electrically connecting the first contact pad with the second contact pad.

9. The packaging method according to claim 1, wherein after the preparing the wafer and before the forming the blind hole from the second surface of the wafer, the packaging method further comprises:
preparing a support substrate; and
forming a first adhesive layer on the first surface of the wafer, and attaching the support substrate with the wafer by using the first adhesive layer.

10. The packaging method according to claim 9, wherein after the attaching the support substrate with the wafer by using the first adhesive layer and before the forming the blind hole from the second surface of the wafer, the packaging method further comprises:
thinning the wafer from the second surface of the wafer.

11. The packaging method according to claim 1, wherein the securing the drive chip in the blind hole comprises:
forming a second adhesive layer on an inner surface of the blind hole; and
securing the drive chip in the blind hole by using the second adhesive layer, with the second surface of the drive chip facing the second adhesive layer.

12. The packaging method according to claim 9, wherein the cutting the wafer comprises:
removing the support substrate and then cutting the wafer to obtain a package structure for the fingerprint recognition chip and the drive chip.

13. The packaging method according to claim 9, wherein the cutting the wafer comprises:
cutting the wafer and then removing the support substrate to obtain a packaging structure for the fingerprint recognition chip and the drive chip.

14. A package structure for a fingerprint recognition chip and a drive chip, comprising:
a fingerprint recognition chip, having a first surface and a second surface facing away from the first surface;
a drive chip, having a first surface and a second surface facing away from the first surface, wherein the first surface of the drive chip is provided with a drive circuit and a second contact pad; and
a blind hole arranged on the second surface of the fingerprint recognition chip, wherein the drive chip is secured in the blind hole, and the first surface of the drive chip is flush with the second surface of the fingerprint recognition chip.

15. The package structure according to claim 14, wherein the fingerprint recognition chip comprises a sensing region and a first contact pad around the sensing region, and the blind hole is arranged in a region corresponding to the sensing region of the fingerprint recognition chip.

16. The package structure according to claim 14, further comprising:
a through hole, formed from the second surface of the fingerprint recognition chip to expose the first contact pad;
a redistribution layer, formed in the through hole and on the second surface of the fingerprint recognition chip and electrically connected to the first contact pad;
a solder bump, arranged on the redistribution layer and electrically connected to the redistribution layer; and
a solder bump, arranged on the second contact pad and electrically connected to the second contact pad.

17. The package structure according to claim 16, wherein the redistribution layer is formed in the through hole and electrically connected to the first contact pad, and the package structure further comprises:
an insulative layer, and
an electrical wiring layer which is electrically connected to the second contact pad, wherein
the insulative layer covers a side wall of the through hole, the second surface of the fingerprint recognition chip and the first surface of the drive chip, the insulative layer is provided with a first opening and the second contact pad is exposed by the first opening, and the redistribution layer covers an inner wall of the through hole and extends to the second surface of the fingerprint recognition chip; and
the electrical wiring layer is arranged on the first opening.

18. The package structure according to claim 16, further comprising: an insulative layer, a metal plug electrically connected to the first contact pad and an electrical wiring layer electrically connected to the second contact pad, wherein
the insulative layer covers a side wall of the through hole, the second surface of the fingerprint recognition chip and the first surface of the drive surface;
the metal plug is arranged on the first contact pad, and fills up the through hole;
the redistribution layer is arranged on the metal plug; and
the electrical wiring layer is arranged on the second contact pad.

19. The package structure according to claim 16, wherein
the through hole is a stepped hole, the stepped hole comprises a groove arranged above the first contact pad and a via hole formed in the groove to expose the first contact pad, the via hole has a one to one correspondence with the first contact pad,
the redistribution layer is formed in the stepped hole and is electrically connected to the first contact pad, and
the package structure further comprises: an insulative layer, and an electrical wiring layer which is electrically connected to the second contact pad;
the insulative layer covers a side wall of the stepped hole, the second surface of the fingerprint recognition chip and the first surface of the drive chip, the insulative layer is provided with a first opening and the second contact pad is exposed by the first opening, the redistribution layer is formed on an inner wall of the stepped hole and extends to the second surface of the fingerprint recognition chip; and
the electrical wiring layer is arranged on the first opening.

20. The package structure according to claim 16, further comprising:
an interconnecting layer electrically connecting the first contact pad with the second contact pad.
